(19) United States
(12) Patent Application Publication
(10) Pub. No.: US 2016/0161843 A1
(43) Pub. Date: Jun. 9, 2016

(54) INTELLIGENT UNIFORM MASKS FOR SEMICONDUCTOR FABRICATION

(71) Applicant: BROADCOM CORPORATION, Irvine, CA (US)

(72) Inventor: Tammy DongLei ZHENG, Fremont, CA (US)

(21) Appl. No.: 14/591,834

(22) Filed: Jan. 7, 2015

Related U.S. Application Data
(60) Provisional application No. 62/089,189, filed on Dec. 8, 2014.

(51) Int. Cl. G03F 1/42; H01L 21/768

(52) U.S. Cl. CPC G03F 1/42; H01L 21/76879

(57) ABSTRACT

A method for reducing pattern density effects in semiconductor fabrication includes forming a first mask that includes one or more arrays of uniformly distributed pattern. Each array of the uniformly distributed pattern includes similar pattern elements having similar dimensions, orientations, and distances. Using the first mask allows forming a layer of semiconductor devices based on the first mask with reduced pattern density effects. A second mask is formed for the layer based on the first mask. The second mask includes undesired portions, for which the pattern is not uniform. Using the second mask allows removing the undesired portions of the formed layer of the semiconductor devices to create desired structures on the formed layer without a need for using optical proximity correction (OPC).

### CROSS-REFERENCE TO RELATED APPLICATIONS

This application claims the benefit of priority under 35 U.S.C. §119 from U.S. Provisional Patent Application 62/089,189 filed Dec. 8, 2014, which is incorporated herein by reference in its entirety.

### TECHNICAL FIELD

The present description relates generally to semiconductor fabrication, and more particularly, but not exclusively, to intelligent uniform masks for semiconductor fabrication.

### BACKGROUND

Mitigating pattern density effects on semiconductor processing is one of the top challenges of semiconductor fabrication. Pattern density effects can occur in photolithography, plasma etching, chemical mechanical polishing (CMP), plating, and other fabrication processing steps. Due to the pattern density effects, after photolithography processing, the patterns transferred to wafers (e.g., silicon wafers) can be substantially different from the patterns on the masks. The differences between the patterns on the wafers and on the masks could significantly vary, depending not only on the patterns themselves, but also depending largely on the surrounding areas, the photolithography process equipment tools, and process conditions. The pattern density effects include irregularities (e.g., rounding of right-angle corners, and changing widths and/or lengths) in masked patterns such as lines after photolithography due to optical proximity. The optical proximity effects can exacerbate when the mask includes a large number of non-uniform features. The pattern density effects can result in device functionality failure, yield impact, marginality issues, reliability issues, different types of variations, and other undesired effects on the fabrication process.

### BRIEF DESCRIPTION OF THE DRAWINGS

Certain features of the subject technology are set forth in the appended claims. However, for purpose of explanation, several embodiments of the subject technology are set forth in the following figures.

FIG. 1 illustrates examples of pattern density effects and applied optical proximity corrections.

FIG. 2 illustrates an example of a first mask including exemplary arrays of uniformly distributed patterns, in accordance with one or more implementations.

FIG. 3 illustrates examples of first and second photo masks including vertical patterns and corresponding first and second hard masks in accordance with one or more implementations.

FIG. 4 illustrates examples of first and second photo masks including horizontal patterns and corresponding first and second hard masks in accordance with one or more implementations.

FIG. 5 illustrates examples of a structure formed on a substrate using the first and second masks including vertical patterns in accordance with one or more implementations.

FIG. 6 illustrates an example of a method for reducing pattern density effects in semiconductor fabrication in accordance with one or more implementations.

FIG. 7 illustrates an example of a method for forming an intelligent uniform mask for semiconductor fabrication, in accordance with one or more implementations.

### DETAILED DESCRIPTION

The detailed description set forth below is intended as a description of various configurations of the subject technology and is not intended to represent the only configurations in which the subject technology can be practiced. The appended drawings are incorporated herein and constitute a part of the detailed description. The detailed description includes specific details for the purpose of providing a thorough understanding of the subject technology. However, it will be clear and apparent to those skilled in the art that the subject technology is not limited to the specific details set forth herein and can be practiced using one or more implementations. In one or more instances, well-known structures and components are shown in block diagram form in order to avoid obscuring the concepts of the subject technology.

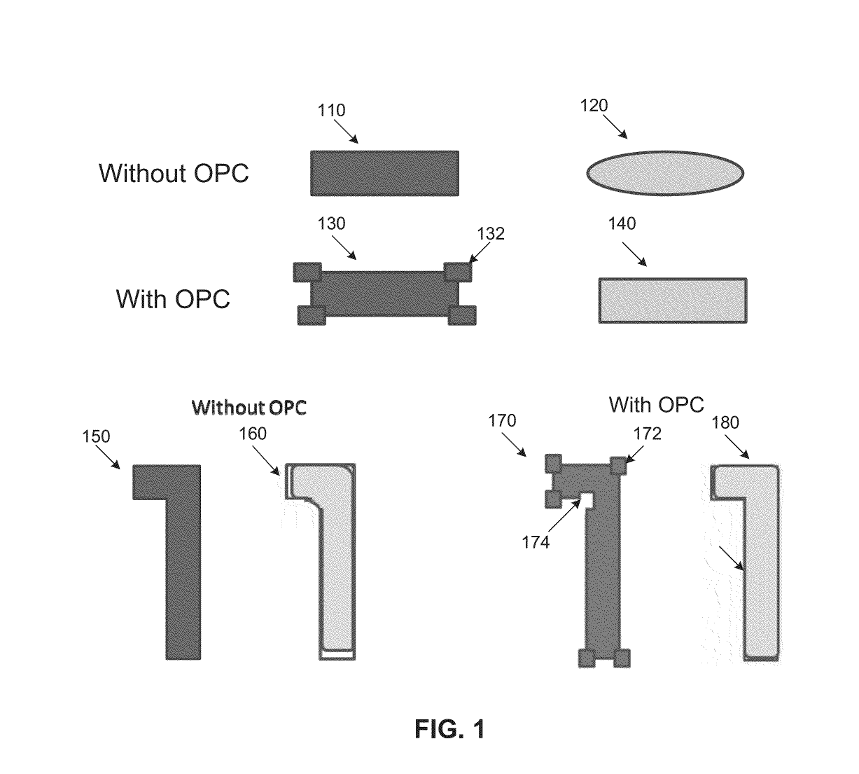

In some aspects of the subject disclosure, methods and implementations for reducing pattern density effects using intelligent masks are disclose. The intelligent masks of the subject technology include a first mask having a number of uniformly distributed pattern elements and a second mask that is used to protect desired potions of the pattern elements of the first mask. The subject technology can significantly reduce pattern density variations on critical steps and critical design areas to achieve better device functionality, performance, yield, and reliability. The subject solution can make foundry fab transfers easier and more efficient. Further, the subject solution allows more aggressive design rules and makes inline defect monitoring and analysis easier. FIG. 1 illustrates examples of pattern density effects and applied optical proximity corrections. The optical proximity correction (OPC) is currently being used to address the pattern density issues. The OPC is mainly performed at the semiconductor fabrication facility (e.g., foundry or fab) and each foundry may use a proprietary OPC process. Therefore, the performed OPC is typically foundry dependent and each foundry has developed its own unique OPC rules (which largely depends on the photolithography process tools, process conditions, and process capabilities of the foundry), for various technology nodes, based on most common existing layout patterns. Examples of OPC rules for simple mask pattern elements such as a rectangular element 110 and an L-shape element 150 are shown in FIG. 1 and discussed herein. The rectangular element 110 can be an element of a high pattern density mask provided to a foundry to be used in a lithography process (e.g., optical lithography) to create a structure of a layer of a semiconductor device (e.g., a gate of a MOS device or a metal interconnect). If the foundry used the same mask in the lithography process, due to pattern density effects, the shape of the created structure would not be the same as the shape of the rectangular element 110. In practice, the actual shape of the created structure can be similar to an oval shape 120, which can adversely affect the performance of the semiconductor device. To address the pattern density effect, the foundry may correct the shape of the rectangular element 110 using OPC rules, for example, by employing additional masks that include sub-elements 132 at corners of the rectangular element 110 to form the post-OPC rectangular element 130 (e.g., after OPC). The post-OPC rectangular element 130 when used in the lithography process can result in a post-OPC created structure 140, the shape of which is quite close to the shape of the rectangular element 110 of the original mask provided to the foundry.

As another example, the mask provided to a foundry may include the L-shape element 150, which if used in the lithography process can result in the created structure 160 that has round corners. The foundry uses additional masks including sub-elements 172 and 174 to change L-shape element 150 to the post-OPC L-shape element 170, which can result in a post-OPC created structure 180 that highly resembles the shape of the original L-shape element 150 of the original mask provided to the foundry. However, for unknown new layout patterns, which can happen quite often, the OPC rules could be insufficient to compensate for the pattern density effect. Another problem can arise when the same design is taped out to different foundries or is transferred from one foundry to another. The original design can be based on one primary foundry's design rules and may not work for other foundries on every single layout pattern.

The subject technology can use highly optimized and smaller sets of OPCs and reduce the implementation of complex and substantially large sets of OPCs, while achieving significantly better and more predictable results on device performance and significantly less device variation.

The subject technology can reduce the need for OPC by disclosing a set of intelligent masks as described herein that can be provided to any foundry for fabrication. The foundry may not need to perform an OPC or may need to perform only minor changes on the set of intelligent masks of the subject technology. The subject technology allows the layout design to be less foundry dependent and be compatible with more aggressive design rules with reduced pattern density issues.

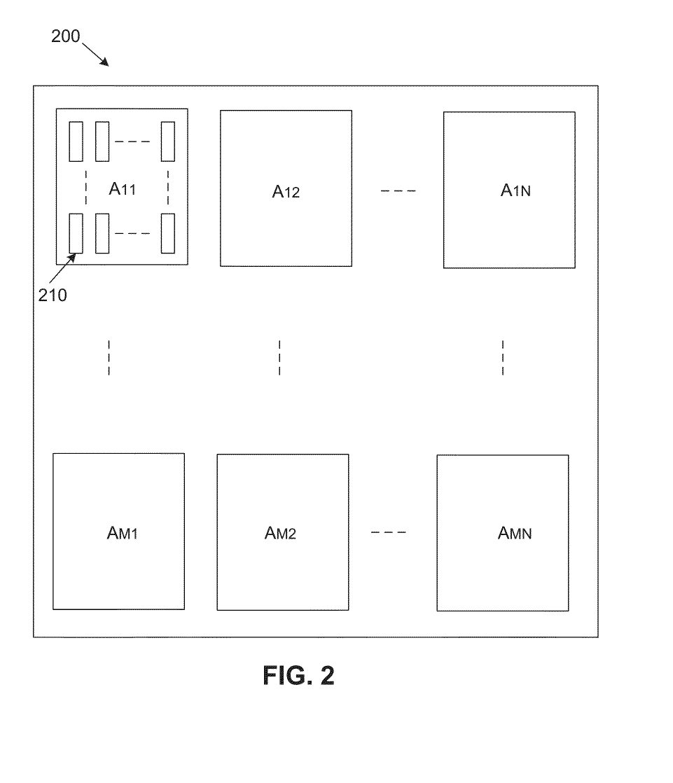

FIG. 2 illustrates an example of a first mask 200 including exemplary arrays of uniformly distributed patterns, in accordance with one or more implementations of the subject technology. The subject technology reduces pattern density effects in semiconductor fabrication by using a first and a second mask for each layer (e.g., including metal or poly gate). The first mask 200 includes a number of arrays of uniformly distributed patterns (e.g., A₁₁ A₁₂ . . . A_{MN}). Each array (e.g., A₁₁) of the uniformly distributed patterns includes multiple similar pattern elements 210 (e.g. vertical rectangles). The pattern elements 210 of each array of uniformly distributed patterns have the same orientation and approximately equal dimensions and inter-element spacing (e.g., distance). In one or more implementations, a pattern in each array (e.g., each of A₁₁ A₁₂ . . . A_{MN}) is uniform in shape and dimension (e.g., width, length and size), orientation and distance (e.g., the distance between the elements horizontally and distance between the elements vertically). In one or more implementations, each array consists of a pattern that is uniform in shape, dimension, orientation and distance. The pattern elements 210 of the first mask 200 are consistent with design rules that define the smallest width, length, and distance of the similar pattern elements.

In one or more implementations, the arrays of uniformly distributed patterns may or may not be similar. Stated in another way, while each array may contain uniformly distributed patterns, a pattern (and/or a shape) contained in one array may be different from a pattern (and/or shape) contained in another array. For example, while the first array A₁ is formed of uniformly distributed vertical rectangles, the other arrays (e.g., any of A₁₂ . . . A_{MN}) can be formed of other pattern elements, such as uniformly distributed horizontal rectangles or other basic shapes, with similar or different dimensions or inter-element distances than of the pattern elements of the array A₁₁. In one or more implementations, the areas of the different arrays do not overlap with each other. For example, the area of array A₁₂ does not overlap with the area of any of the other arrays.

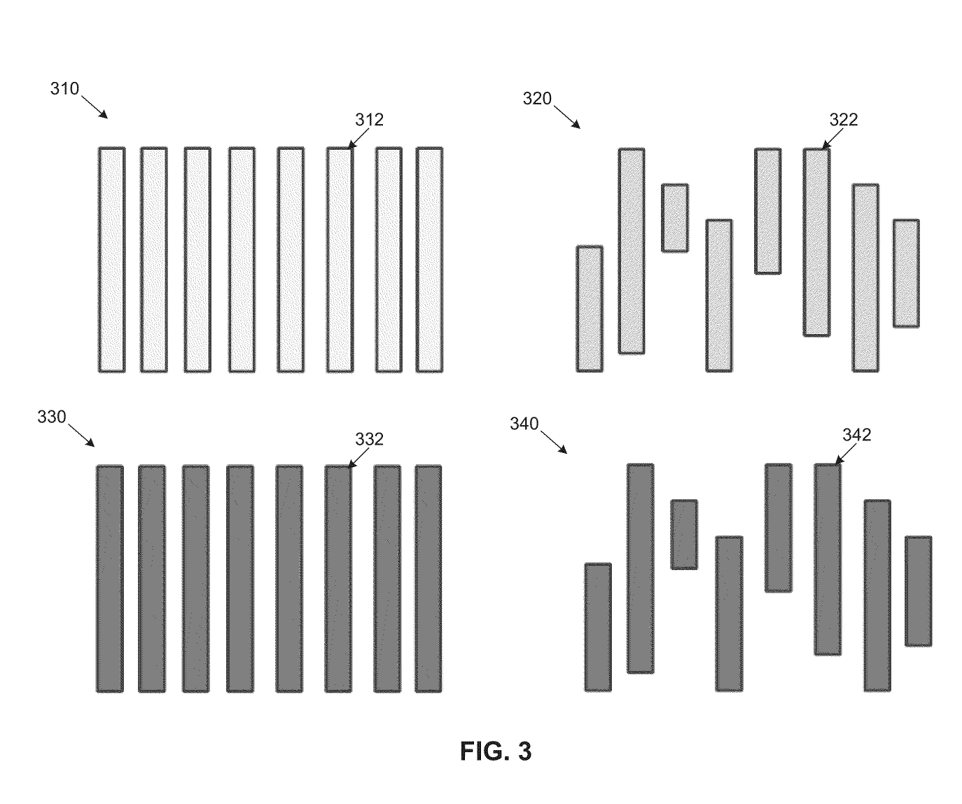

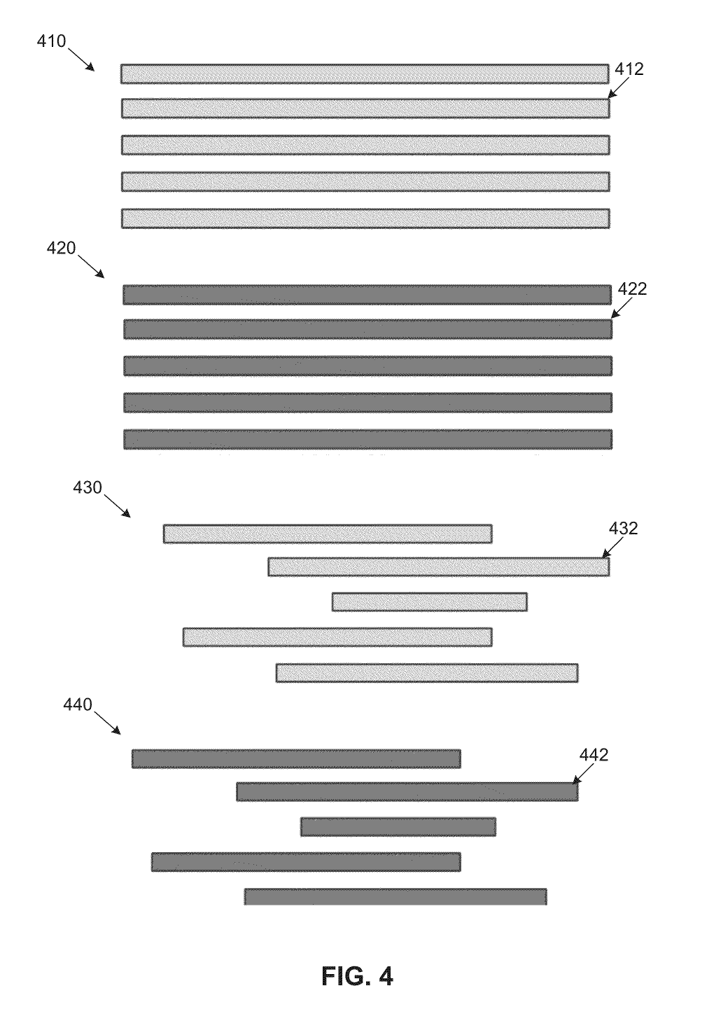

The uniformly distributed pattern elements of the first mask 200 allow reducing pattern density effects in the structures (e.g., rectangular structures) that are formed by using the first mask 200. The first mask, however, does not provide the exact structure as designed. In other words, the actual structure as designed is different from a structure created using the first mask 200. To remove portions of the laid out structure that are not part of the actual design, a second mask is used. The second mask is formed based on the first mask and includes undesired portions of the similar pattern elements of each array of uniformly distributed pattern elements that are not part of the actual design. Using the second mask, undesired portions of the formed layer of the semiconductor devices (e.g., using the first mask 200) can be removed to create desired structures on the formed layer without using OPC. More details of the second mask and its use are described herein, with respect to FIGS. 3 and 4.

In one or more implementations, the devices with different performance characteristics (e.g., transistors with different speeds or powers) can be fabricated by employing different process steps to form the devices that are patterned by the first and second masks. In other words, devices formed by the array of pattern elements A₁₁, can have different performance characteristics than the devices formed by the array of pattern elements A_{M2}, just by using different process steps (e.g., process steps involving different materials, doping level, temperature, etc.), even with similar pattern elements in the arrays A₁₁ and A_{M2}.

FIG. 3 illustrates examples of first and second photo masks 310 and 320 including vertical patterns and corresponding first and second hard masks 330 and 340 in accordance with one or more implementations of the subject technology. The first photo mask 310 includes a number of uniformly distributed pattern elements (e.g., vertical rectangular pattern elements) 312. The pattern elements 312 are approximately or nearly the same dimensions and are nearly equally spaced from one another. Consequently, the first photo mask 310 is expected to have substantially reduced pattern density effects. The first photo mask 310 may be used to create, for example, poly gate structures (e.g., by processes such as photo lithography, etch, gate fill, chemical mechanical polish (CPM), etc.), which are not exactly the same dimensions as the pattern elements 312. The undesired portion of the created structures can be removed by using the second photo mask 320, which when used in the photolithography process, protects the desired portions and enables removal of the undesired portions (e.g., 322) corresponding to the structures formed by using the first photo mask 310 (e.g., pattern element 312).

In one or more implementations, the first and second photo masks 310 and 320 can be transferred to hard masks 330 and 340 with respective pattern elements 332 and 342. The hard masks can be used for etch processes such as a plasma etch. It is understood that using the second mask (e.g., 320 or 340) does not contribute to pattern density effects, because the second mask is used to remove the undesired portions of the formed layer of the semiconductor devices, for which the pattern density effects are less critical.

FIG. 4 illustrates examples of first and second photo masks 410 and 430 including horizontal patterns and corresponding first and second hard masks 420 and 440 in accordance with one or more implementations of the subject technology. The first photo mask 410 includes a number of uniformly distributed pattern elements (e.g., horizontal rectangular pattern elements) 412. The pattern elements 412 are nearly the same dimensions and are approximately equally spaced from one another. Consequently, the first photo mask 410 is not expected to cause pattern density effects. The first photo mask 410 may be used to create, for example, metal layers, which are not exactly the same dimensions as the pattern elements 412. The undesired portion of the created structures can be removed by using the second photo mask 430, which when used in the photolithography process, protects the desired portions and enables removal of the undesired portions (e.g., 432) corresponding to the metal layers formed by using the first photo mask 410 (e.g., pattern element 412).

In one or more implementations, the first and second photo masks 410 and 430 can be transferred to hard masks 420 and 440 with respective pattern elements 422 and 442. The hard masks can be used for etch processes such as a plasma etch. It is understood that using the second mask (e.g., 420 or 440) does not contribute to pattern density effects, because the second mask is used to remove the undesired portions of the formed layer of the semiconductor devices, for which the pattern density effects are less critical. In one or more implementations, a mask may be in an electronic software form. In one or more implementations, a hard mask may be a physical tangible mask that is not in software form. In one or more implementations, a hard mask is used in the fabrication steps of a semiconductor device on a substrate.

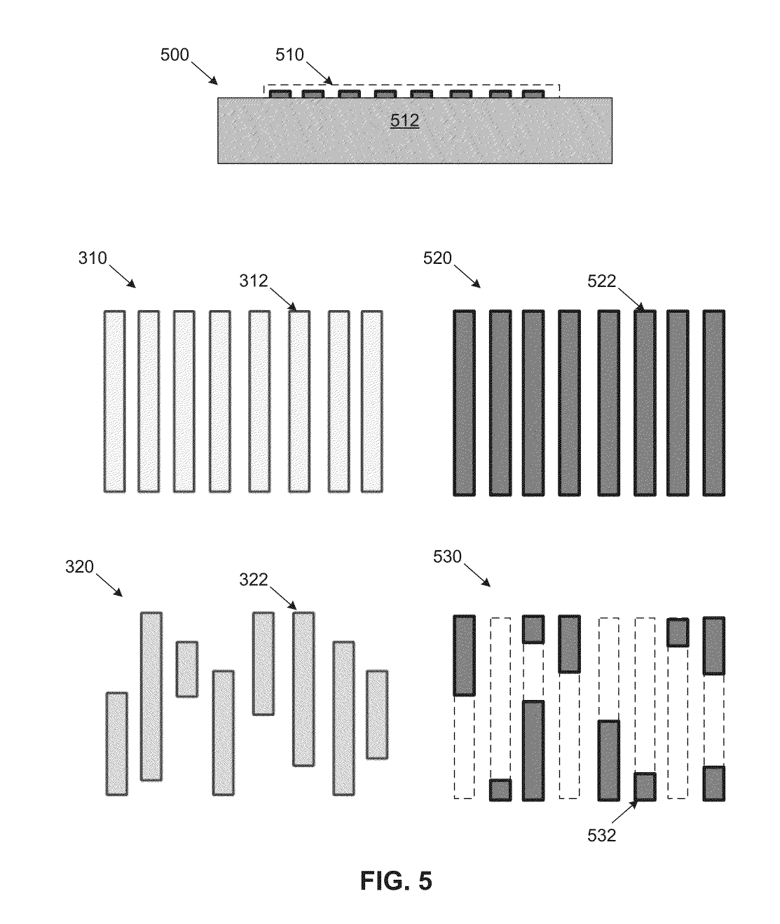

FIG. 5 illustrates examples of a structure 510 formed on a substrate 512 using the first and second masks 310 and 320 including vertical patterns in accordance with one or more implementations of the subject technology. In some implementations, a layer including a structure 510 (e.g., poly gates) of a semiconductor device 500 can be created by using the first mask 310 and the second mask 320. The first mask 310 includes uniformly distributed pattern structure, for example, vertically oriented rectangular elements (e.g., 312) and, due to its uniformity, allows forming the layer of the semiconductor device 500 (e.g. as shown in the top view 520, including sub-structures 522) with none or reduced pattern density effects. The first mask 310 is used with positive photoresist to create the layer 520. The second mask 320 is based on the first mask 310 and includes the undesired portions of the layer 520, which are not uniform. Using the second mask 320 and a negative photoresist allows for removing the undesired portions of the structure 520, which result in a final form of the structure 510, as shown in the top view 530. Due to the use of the negative photoresist, the shape of the structures (e.g., 532) in the top view 530 complements the shape of the pattern elements (e.g., 322) of the second mask 320 and is substantially free from pattern density effects.

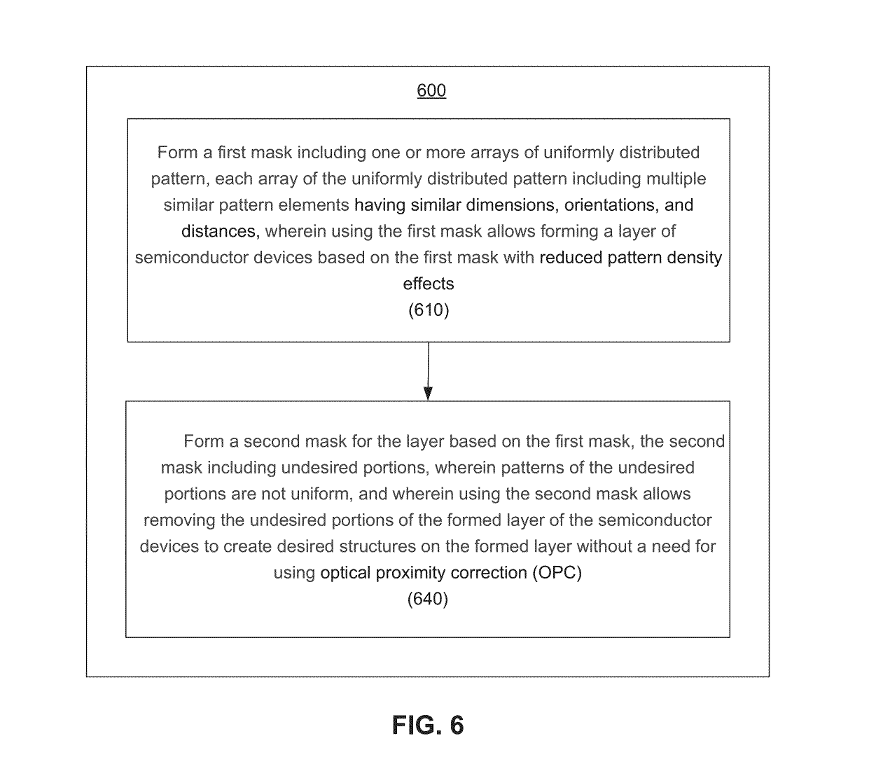

FIG. 6 illustrates an example of a method 600 for reducing pattern density effects in semiconductor fabrication in accordance with one or more implementations of the subject technology. For explanatory purposes, the example method 600 is described herein with reference to, but is not limited to, the process disclosed with respect the FIGS. 2, 3, 4 and 5. Further, for explanatory purposes, the blocks of the example method 600 are described herein as occurring in serial, or linearly. However, multiple blocks of the example method 600 can occur in parallel.

According to the method 600, a first mask (e.g., 200 of FIG. 2) including one or more arrays of uniformly distributed pattern is formed (610). Each array (e.g., A₁₁ of FIG. 2 or 310 of FIG. 3) of the uniformly distributed pattern includes multiple similar pattern elements (e.g., 210 of FIG. 2 or 312 of FIG. 3) having similar dimensions, orientations, and distances. Using the first mask allows forming a layer (e.g., 520 of FIG. 5) of semiconductor devices based on the first mask with reduced pattern density effects. A second mask (e.g., 320 of FIG. 3 or 430 of FIG. 4) is formed for the layer that is based on the first mask and includes undesired portions including a pattern that is not uniform (620). Using the second mask allows removing the undesired portions (e.g., 320 of FIG. 5) of the formed layer of the semiconductor devices to create desired structures (e.g., 530 of FIG. 5) on the formed layer without a need for using optical proximity correction (OPC).

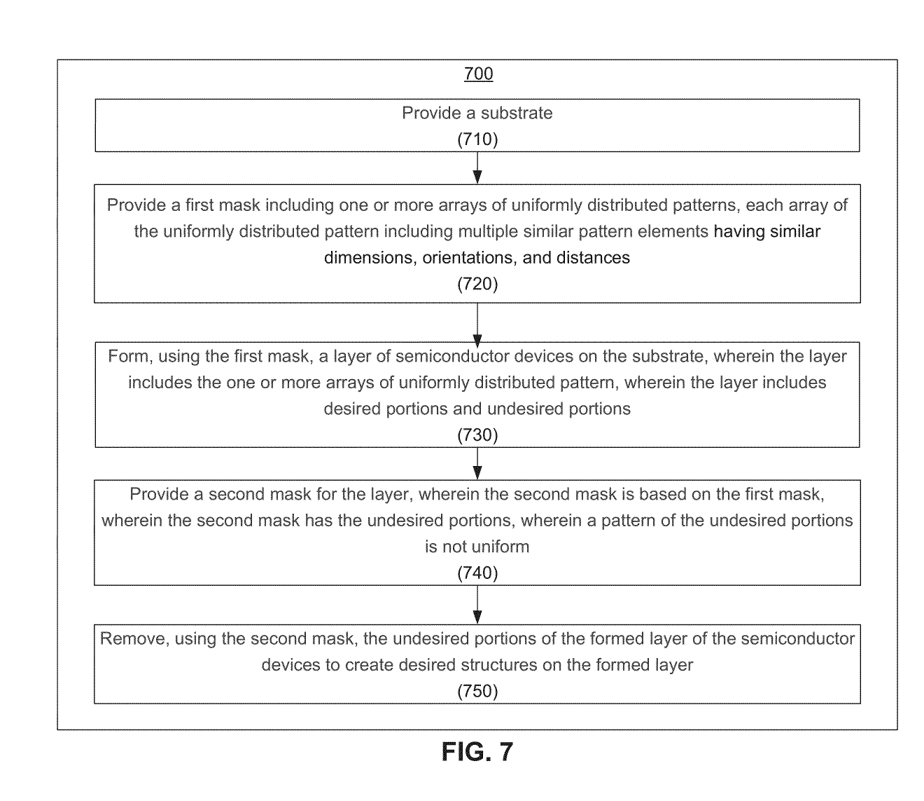

FIG. 7 illustrates an example of a method 700 for forming an intelligent uniform mask for semiconductor fabrication, in accordance with one or more implementations of the subject technology. For explanatory purposes, the example method 700 is described herein with reference to, but is not limited to, the process disclosed with respect the FIGS. 2 and 5. Further, for explanatory purposes, the blocks of the example method 700 are described herein as occurring in serial, or linearly. However, multiple blocks of the example method 700 can occur in parallel. In addition, the blocks of the example method 700 need not be performed in the order shown and/or one or more of the blocks of the example method 700 need not be performed.

According to the method 700, a substrate (e.g., 512 of FIG. 5) is provides (710). A first mask (e.g., 200 of FIG. 2) including one or more arrays (e.g., A₁₁ of FIG. 2 or 310 of FIG. 5) of uniformly distributed patterns is provided (720). Each array of the uniformly distributed patterns includes multiple similar pattern elements (e.g., 210 of FIG. 2 or 312 of FIG. 5) having similar dimensions, orientations, and distances. Using the first mask, a layer of semiconductor device (e.g., 510 of FIG. 5) on the substrate is formed that includes the one or more arrays of uniformly distributed patterns (730). The layer includes desired portions (e.g., 530 of FIG. 5) and undesired portions (e.g., shown by 322 of FIG. 5). A second mask (e.g., 320 of FIG. 5) for the layer is provided (740). The second mask is based on the first mask and has the undesired portions that include patterns that are not uniform. Using the second mask, the undesired portions of the formed layer of the semiconductor devices are removed to create desired structures (e.g., 530 of FIG. 5) on the formed layer (750).

Those of skill in the art would appreciate that the various illustrative blocks, modules, elements, components, and methods described herein can be implemented as electronic hardware, computer software, or combinations of both. To illustrate this interchangeability of hardware and software, various illustrative blocks, modules, elements, components, and methods have been described above generally in terms of their functionality. Whether such functionality is implemented as hardware or software depends upon the particular application and design constraints imposed on the overall system. Skilled artisans can implement the described functionality in varying ways for each particular application. Various components and blocks can be arranged differently (e.g., arranged in a different order, or partitioned in a different way) all without departing from the scope of the subject technology.

As used herein, the phrase “at least one of” preceding a series of items, with the term “and” or “or” to separate any of the items, modifies the list as a whole, rather than each member of the list (i.e., each item). The phrase “at least one of” does not require selection of at least one of each item listed; rather, the phrase allows a meaning that includes at least one of any one of the items, and/or at least one of any combination of the items, and/or at least one of each of the items. By way of example, the phrases “at least one of A, B, and C” or “at least one of A, B, or C” each refer to only A, only B, or only C; any combination of A, B, and C; and/or at least one of each of A, B, and C.

Phrases such as an aspect, the aspect, another aspect, some aspects, one or more aspects, an implementation, the implementation, another implementation, some implementations, one or more implementations, an embodiment, the embodiment, another embodiment, some embodiments, one or more embodiments, a configuration, the configuration, another configuration, some configurations, one or more configurations, the subject technology, the disclosure, the present disclosure, other variations thereof and alike are for convenience and do not imply that a disclosure relating to such phrase(s) is essential to the subject technology or that such disclosure applies to all configurations of the subject technology. A disclosure relating to such phrase(s) may apply to all configurations, or one or more configurations. A disclosure relating to such phrase(s) may provide one or more examples. A phrase such as an aspect or some aspects may refer to one or more aspects and vice versa, and this applies similarly to other foregoing phrases

The word “exemplary” is used herein to mean “serving as an example, instance, or illustration.” Any embodiment described herein as “exemplary” or as an “example” is not necessarily to be construed as preferred or advantageous over other embodiments. Furthermore, to the extent that the term “include,” “have,” or the like is used in the description or the claims, such term is intended to be inclusive in a manner similar to the term “comprise” as “comprise” is interpreted when employed as a transitional word in a claim.

All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112, sixth paragraph, unless the element is expressly recited using the phrase “means for” or, in the case of a method claim, the element is recited using the phrase “step for.”

The previous description is provided to enable any person skilled in the art to practice the various aspects described herein. Various modifications to these aspects will be readily apparent to those skilled in the art, and the generic principles defined herein can be applied to other aspects. Thus, the claims are not intended to be limited to the aspects shown herein, but are to be accorded the full scope consistent with the language claims, wherein reference to an element in the singular is not intended to mean “one and only one” unless specifically so stated, but rather “one or more.” Unless specifically stated otherwise, the term “some” refers to one or more. Pronouns in the masculine (e.g., his) include the feminine and neuter gender (e.g., her and its) and vice versa. Headings and subheadings, if any, are used for convenience only and do not limit the subject disclosure.

1. A method for forming an intelligent uniform mask for semiconductor fabrication, the method comprising:
forming a first mask including one or more arrays of uniformly distributed pattern, each array of the uniformly distributed pattern comprising a plurality of similar pattern elements having similar dimensions, orientations, and distances, wherein using the first mask allows forming a layer of semiconductor devices based on the first mask with reduced pattern density effects; and
forming a second mask for the layer, wherein the second mask is based on the first mask, wherein the second mask includes undesired portions, wherein a pattern of the undesired portions is not uniform, and wherein using the second mask allows removing the undesired portions of the formed layer of the semiconductor devices to create desired structures on the formed layer without a need for using optical proximity correction (OPC).

2. The method of claim 1, wherein the plurality of similar pattern elements comprise a plurality of rectangles, wherein forming the first mask comprises forming the plurality of rectangles that are laid out horizontally or vertically.

3. The method of claim 1, wherein forming the first mask comprises forming the plurality of similar pattern elements consistent with design rules defining a smallest width, a smallest length, and a smallest distance of the plurality of similar pattern elements.

4. The method of claim 1, wherein:
each array comprises a pattern that is uniform in shape, dimension, orientation and distance, and
using the second mask to remove the undesired portions of the formed layer of the semiconductor devices does not contribute to pattern density effects.

5. The method of claim 1, wherein the first mask comprises a uniform poly mask or a partially uniform poly mask.

6. The method of claim 5, wherein forming the layer of the semiconductor devices comprises creating poly gate structures, and wherein the undesired portions of the formed layer of the semiconductor devices comprises unwanted poly gates.

7. A method for reducing pattern density effects in semiconductor fabrication, the method comprising:
providing a substrate;
providing a first mask including one or more arrays of uniformly distributed pattern, each array of the uniformly distributed pattern comprising a plurality of similar pattern elements having similar dimensions, orientations, and distances;
forming, using the first mask, a layer of semiconductor devices on the substrate, wherein the layer comprises the one or more arrays of uniformly distributed pattern, wherein the layer comprises desired portions and undesired portions;
providing a second mask for the layer, wherein the second mask is based on the first mask, wherein the second mask has the undesired portions, wherein a pattern of the undesired portions are not uniform; and
removing, using the second mask, the undesired portions of the formed layer of the semiconductor devices to create desired structures on the formed layer.

8. The method of claim 7, wherein the first mask comprises a uniform poly mask or a partially uniform poly mask, wherein forming the layer of the semiconductor devices on the substrate comprises creating poly gate structures, and wherein the undesired portions of the formed layer of the semiconductor devices comprises unwanted poly gates.

9. The method of claim 7, wherein using the first mask allows forming the layer of the semiconductor devices based on the first mask with reduced pattern density effects.

10. The method of claim 7, wherein using the second mask allows removing the undesired portions of the formed layer of the semiconductor devices to create desired structures on the formed layer without a need for using optical proximity correction (OPC).

11. The method of claim 7, further comprising forming devices with different performance characteristics by employing the first and the second mask to pattern the devices and using different process steps to form the devices patterned by the first and second masks.

12. The method of claim 7, wherein the plurality of similar pattern elements comprise a plurality of rectangles, wherein providing the first mask comprises forming the plurality of rectangles that are laid out horizontally or vertically.

13. The method of claim 7, wherein providing the first mask comprises forming the plurality of similar pattern elements consistent with design rules defining a smallest width, a smallest length, and a smallest distance of the plurality of similar pattern elements.

14. The method of claim 7, wherein the first mask comprises a uniform metal mask or a partially uniform metal mask, wherein forming the layer of the semiconductor devices on the substrate comprises creating metal layers, and wherein the undesired portions of the formed layer of the semiconductor devices comprises unwanted metals.

15. A set of masks for reducing pattern density effects in semiconductor fabrication, the set of masks comprising:
a first mask including one or more arrays of uniformly distributed pattern and configured to facilitate forming a layer of semiconductor devices with reduced pattern density effects; and
a second mask formed based on the first mask, the second mask including undesired portions and configured to facilitate removing the undesired portions of the formed layer of the semiconductor devices to create desired structures on the formed layer without a need for using optical proximity correction (OPC),
wherein:
each array of the uniformly distributed pattern comprises a plurality of similar pattern elements having similar dimensions, orientations, and distances, and
a pattern of the undesired portions is not uniform.

16. The set of masks of claim 15, wherein the first mask is configured to facilitate creating poly gate structure.

17. The set of masks of claim 15, wherein the first mask comprises the plurality of similar pattern elements consistent with design rules that define a smallest width, a smallest length, and a smallest distance of the plurality of similar pattern elements.

18. The set of masks of claim 15, wherein the plurality of similar pattern elements comprise a plurality of rectangles.

19. The set of masks of claim 15, wherein the first and the second masks are configured to facilitate forming devices with different performance characteristics.

20. The set of masks of claim 15, wherein the first mask is configured to facilitate creating metal layers.

21. The set of masks of claim 15, wherein the undesired portions of the formed layer of the semiconductor devices comprise unwanted poly gates.

22. The set of masks of claim 18, wherein the plurality of rectangles are laid out horizontally or vertically.

23. The set of masks of claim 15, wherein the first and the second mask are employed to pattern the devices and different process steps are used to form the devices with different performance characteristics that are patterned by the first and second masks.

24. The set of masks of claim 20, wherein the undesired portions of the formed layer of the semiconductor devices comprise unwanted metals.

25. A set of masks for reducing pattern density effects, the set of masks comprising:
a first mask for forming a layer including devices with reduced pattern density effects; and
a second mask for removing undesired portions of the formed layer of devices to create desired structures on the formed layer without a need for using optical proximity correction (OPC),
wherein:
the first mask includes one or more arrays of uniformly distributed pattern,
the second mask is formed based on the first mask and includes the undesired portions, and
each array of the uniformly distributed pattern comprises a plurality of similar pattern elements having similar dimensions, orientations, and distances.

26. The set of masks of claim 25, wherein a pattern of the undesired portions is not uniform, and wherein the layer including devices comprises semiconductor devices.

27. The set of masks of claim 25, wherein the first mask is configured to facilitate creating poly gate structures, and wherein the undesired portions of the formed layer of the devices comprise unwanted poly gates.

28. The set of masks of claim 25, wherein the first mask comprises the plurality of similar pattern elements consistent with design rules that define a smallest width, a smallest length, and a smallest distance of the plurality of similar pattern elements.

29. The set of masks of claim 25, wherein the plurality of similar pattern elements comprise a plurality of rectangles.

30. The set of masks of claim 29, wherein the plurality of rectangles are laid out horizontally or vertically.

31. The set of masks of claim 25, wherein the first and the second masks are configured to facilitate forming devices with different performance characteristics.

32. The set of masks of claim 25, wherein the first mask is configured to facilitate creating metal layers, wherein the undesired portions of the formed layer of the devices comprise unwanted metals.

33. The set of masks of claim 25, wherein the first and the second mask are employed to pattern the devices and different process steps are used to form the devices with different performance characteristics that are patterned by the first and second masks.

34. A set of masks for reducing pattern density effects, the set of masks comprising:
a first mask including one or more arrays of uniformly distributed pattern and configured to facilitate forming a layer of devices with reduced pattern density effects; and
a second mask formed based on the first mask, the second mask including undesired portions and configured to facilitate removing the undesired portions of the formed layer of the devices to create desired structures on the formed layer without a need for using optical proximity correction (OPC),
wherein:
each array of the uniformly distributed pattern comprises a plurality of similar pattern elements, and
a pattern of the undesired portions is not uniform.
